(19) United States
(12) Patent Application Publication
(10) Pub. No.: US 2026/0304787 A1
(43) Pub. Date: Oct. 1, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 19/192,292

(22) Filed: Apr. 28, 2025

(30) Foreign Application Priority Data
Mar. 26, 2025 (TW) 114111485

(51) Int. Cl. H10B 63/00; H10N 70/00; H10N 70/20

(52) U.S. Cl. CPC H10B 63/30; H10N 70/063; H10N 70/24; H10N 70/8265

(57) ABSTRACT

A method for fabricating resistive random access memory (RRAM) device includes the steps of first forming an interlayer dielectric (ILD) layer on a substrate, forming a contact plug in the ILD layer, forming a RRAM on the contact plug, forming a first cap layer and a second cap layer on the RRAM, and removing part of the second cap layer to form a spacer.

### BACKGROUND OF THE INVENTION

### 1. Field of the Invention

The invention relates to a semiconductor device, and more particularly to a resistive random access memory (RRAM) device and fabrication method thereof.

### 2. Description of the Prior Art

Non-volatile memory devices have the advantages of retaining data even if the electrical power is being cut off, hence non-volatile memory devices have been widely used in most appliances today for maintaining proper operation of the electronic products. Currently, a popular non-volatile memory device being developed today is referred to as resistive random access memory (RRAM), which has the advantages of low voltage and short erase time under write operation, long memory duration, no damage under read operation, multiphase memory, simple structure, and small size. With all these benefits, RRAM devices are likely to be used in various personal computers and electronic equipment in the coming future.

In integrated circuits, RRAM is a merging technology applied for the next generation non-volatile memory devices. Specifically, RRAM is a memory structure having a resistive random access memory array, in which each of the resistive random access memory units uses resistance values to store one bit of data instead of electrical potentials. In particular, each of the resistive random access memory units include a resistance material layer that could be used to adjust resistance value for demonstrating “0” or “1”.

One approach to optimize RRAM array is to minimize its size as much as possible. Nevertheless, as size of the device decrease, fabrication cost and complexity also increase accordingly. Hence, how to lower the overall cost while maintaining yield of the product has become a major challenge in this field.

### SUMMARY OF THE INVENTION

According to an embodiment of the present invention, a method for fabricating resistive random access memory (RRAM) includes the steps of first forming an interlayer dielectric (ILD) layer on a substrate, forming a contact plug in the ILD layer, forming a RRAM on the contact plug, forming a first cap layer and a second cap layer on the RRAM, and removing part of the second cap layer to form a spacer.

According to another aspect of the present invention, a resistive random access memory (RRAM) device includes an interlayer dielectric (ILD) layer on a substrate, a contact plug in the ILD layer, a RRAM on the contact plug, a cap layer adjacent to the RRAM, and a spacer adjacent to the cap layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a semiconductor device according to an embodiment of the present invention.

### DETAILED DESCRIPTION

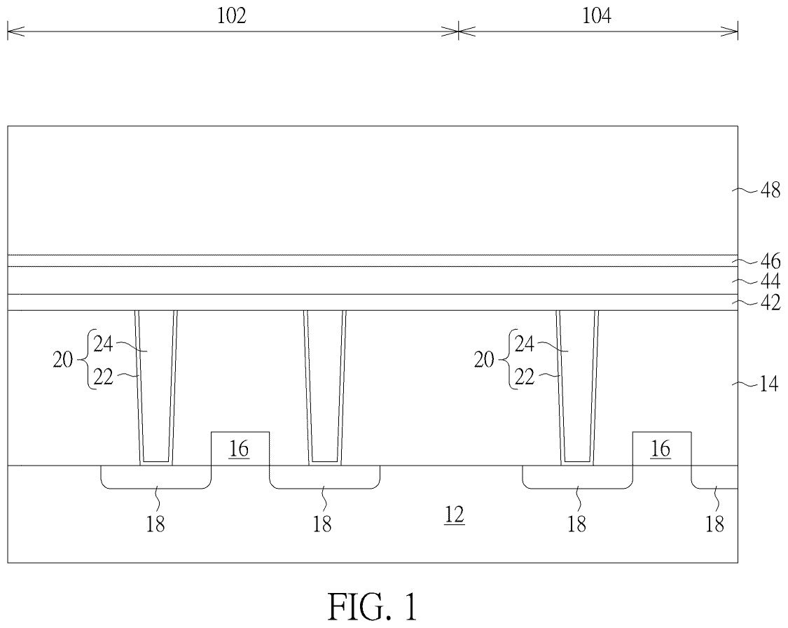

Referring to FIGS. 1-8, FIGS. 1-8 illustrate a method for fabricating a semiconductor device, or more specifically a RRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a memory region 102 and a logic region 104 are defined on the substrate 12.

Active devices such as metal-oxide semiconductor (MOS) transistors, passive devices, conductive layers, and interlayer dielectric (ILD) layer 14 could also be formed on top of the substrate 12 on both memory region 102 and logic region 104. More specifically, planar MOS transistors or non-planar (such as FinFETs) MOS transistors could be formed on the substrate 12, in which the MOS transistors could include transistor elements such as gate structures 16 (for example metal gates) and source/drain regions 18, spacer, epitaxial layer, and contact etch stop layer (CESL). The ILD layer 14 could be formed on the substrate 12 to cover the MOS transistors, and a plurality of contact plugs 20 could be formed in the ILD layer 14 to electrically connect to the gate structures 16 and/or source/drain regions 18 of MOS transistors. Since the fabrication of planar or non-planar transistors and ILD layer is well known to those skilled in the art, the details of which are not explained herein for the sake of brevity.

In this embodiment, the formation of the contact plugs 20 could be accomplished by first conducting a pattern transfer process by using a patterned mask (not shown) as mask to remove part of the ILD layer 14 on the memory region 102 and logic region 104 for forming contact holes (not shown) exposing the source/drain regions 18 underneath. Next, metal or conductive materials including a barrier layer 22 selected from the group consisting of titanium (Ti), titanium nitride (TiN), tantalum (Ta), and tantalum nitride (TaN) and a metal layer 24 selected from the group consisting of tungsten (W), copper (Cu), aluminum (Al), titanium aluminide (TiAl), and cobalt tungsten phosphide (CoWP) are deposited into the contact holes, and then a planarizing process such as chemical mechanical polishing (CMP) process is conducted to remove part of the metal for forming contact plugs 20 or metal interconnections in the contact holes electrically connecting the source/drain regions 18.

Next, a bottom electrode 42, a resistor switching layer 44, a capping layer 46, and a top electrode (TE) 48 are formed on the surface of the ILD layer 14. In this embodiment, the bottom electrode 42 preferably includes metal nitride such as TaN, the resistor switching layer 44 includes a metal oxide layer such as TaO or hafnium oxide (HfO₂), the capping layer 46 includes metal such as iridium (Ir), and the top electrode 48 includes metal nitride such as metal nitride or metal oxide such as tantalum nitride (TaO) or TiN.

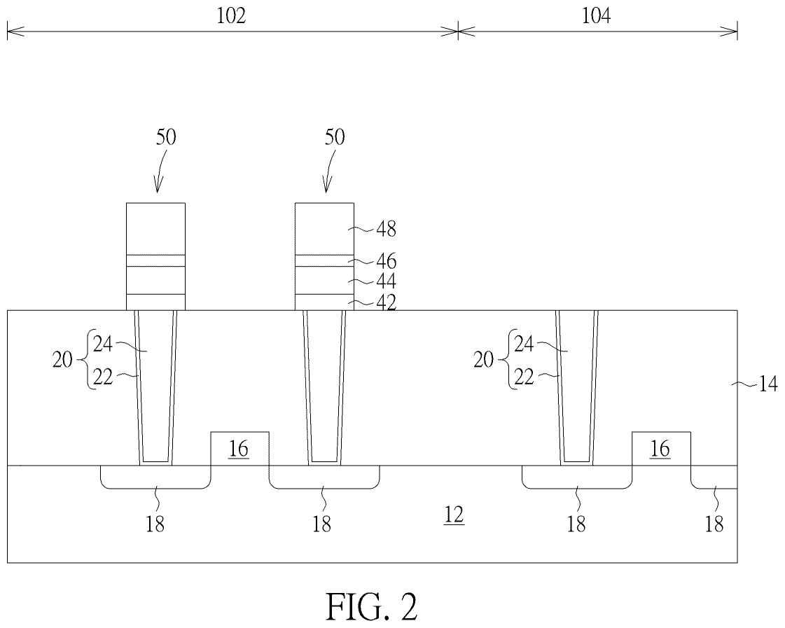

Next, as shown in FIG. 2, one or more etching processes could be conducted by using a patterned mask (not shown) as mask to remove all the top electrode 48, all the capping layer 46, all the resistor switching layer 44, and all the bottom electrode 42 on the logic region 104 and part of the top electrode 48, part of the capping layer 46, part of resistor switching layer 44, and part of the bottom electrode 42 on the memory region 102. This forms a RRAM 50 made of patterned bottom electrode 42, patterned resistor switching layer 44, patterned capping layer 46, and patterned top electrode 48 on the memory region 102. In this embodiment, the etching process conducted to form the RRAM 50 could include reactive ion etching (RIE) or ion beam etching (IBE) process, but not limited thereto.

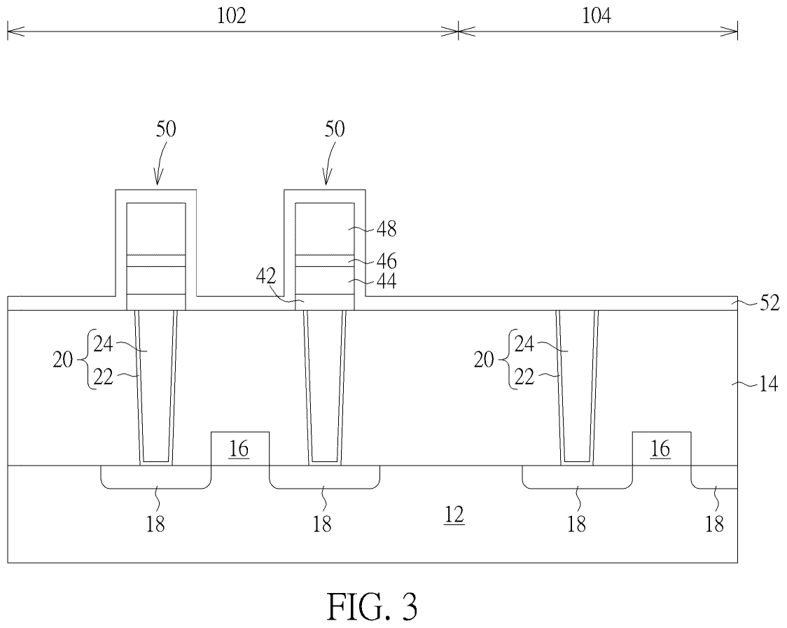

Next, as shown in FIG. 3, a cap layer 52 is formed on the memory region 102 and logic region 104 to cover the top surface and sidewalls of the RRAM 50 as well as the surface of the ILD layer 14. Preferably, the cap layer 52 includes dielectric material such as silicon oxycarbide (SiOC). Nevertheless, according to other embodiment of the present invention, the cap layer 52 could also include silicon carbon nitride (SiCN) or silicon nitride (SiN), which is also within the scope of the present invention.

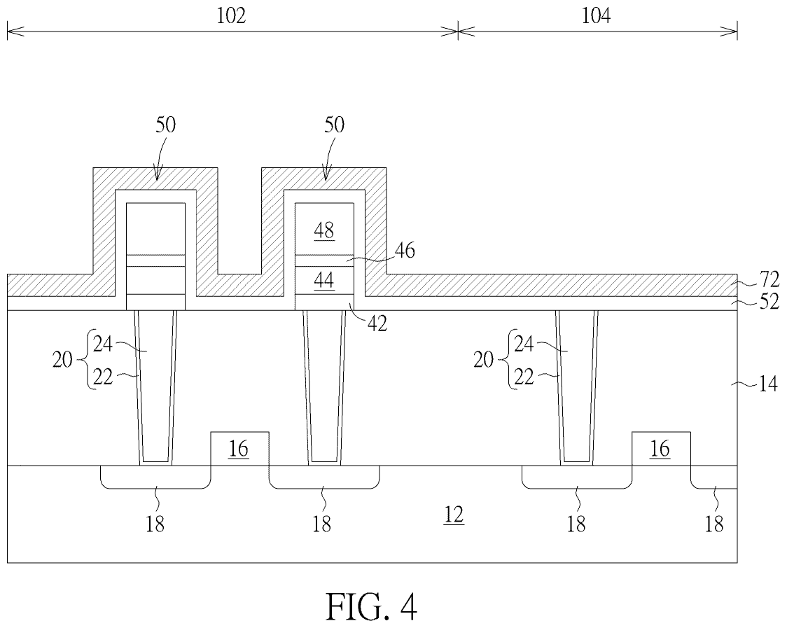

Next, as shown in FIG. 4, another cap layer 72 is formed to cover the surface of the cap layer 52 entirely. In this embodiment, the cap layer 52 and the cap layer 72 are preferably made of different materials, in which the cap layer 52 includes SiOC as disclosed previously while the cap layer 72 includes SiN, SiCN, silicon oxynitride (SiON), or silicon oxide (SiO₂). Moreover, the thickness of the cap layer 72 formed at this stage is greater than the thickness of the cap layer 52. For instance, the thickness of the cap layer 72 could be more than once, twice, three times or even greater than four times the thickness of the cap layer 52, which are all within the scope of the present invention.

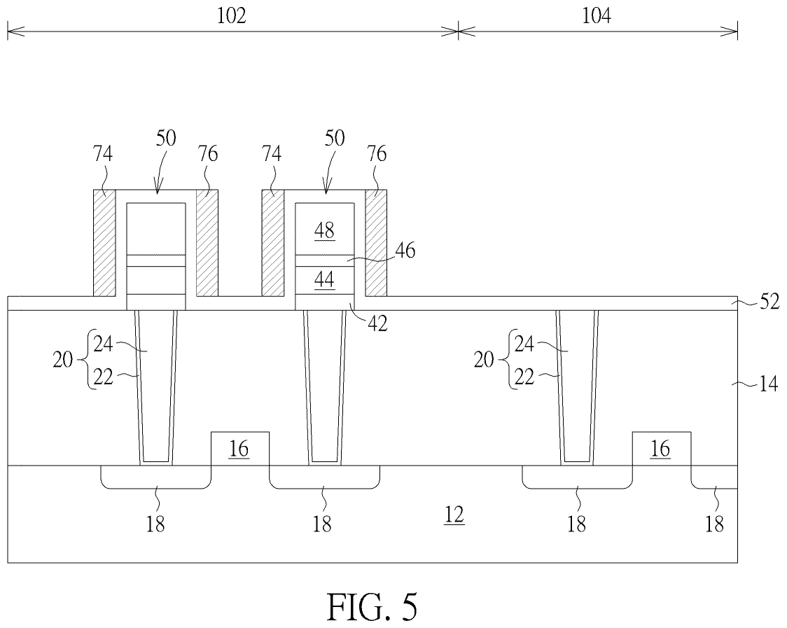

Next, as shown in FIG. 5, an etching back process is conducted without forming additional patterned mask such as patterned resist to remove part of the cap layer 72 for forming spacers 74, 76 adjacent to the cap layer 52. Specifically, the etching back process conducted at this stage removes part of cap layer 72 directly above the RRAM 50 and part of the cap layer 72 adjacent to two sides of the RRAM 50 so that the remaining cap layer 72 forms spacers 74, 76 on sidewalls of the cap layer 52 adjacent to two sides of the RRAM 50. Preferably, top surfaces of the spacers 74, 46 and the first cap layer 52 are coplanar and each of the spacers 74, 76 has an I-shape cross-section as the cap layer 52 has an L-shape cross-section.

It should be noted if viewing from a top view perspective, the spacers 74, 76 are essentially a single spacer around the entire RRAM 50. However, if viewed from a cross-section perspective, the spacers 74, 76 are disposed on left sidewall and right sidewall of the cap layer 52 that is adjacent to two sides of the RRAM 50. Preferably, top surfaces of the spacers 74, 76 are even with the top surface of the cap layer 52 but slightly higher than the top surface of the RRAM 50 while the bottom surfaces of the spacers 74, 76 are slightly higher than the bottom surfaces of the RRAM 50 and cap layer 52. At this stage, the width of each of the spacers 74, 76 could be greater than once, twice, three times, or even more than four times the width of the cap layer 52, which are all within the scope of the present invention.

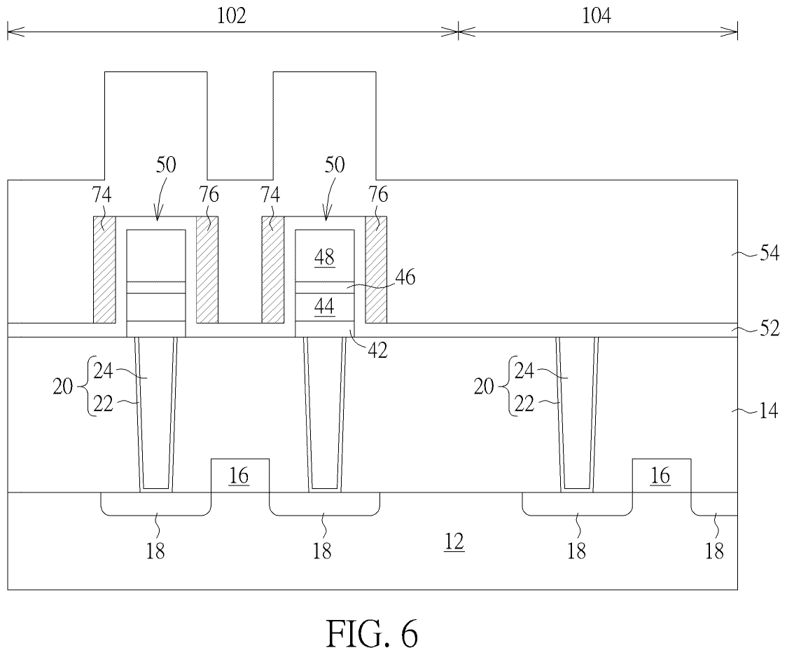

Next, as shown in FIG. 6, a flowable chemical vapor deposition (FCVD) process could be conducted to form an inter-metal dielectric (IMD) layer 54 on ILD layer 14 on the memory region 102 and the logic region 104 to cover the spacers 74, 76 and the cap layer 52. In this embodiment, the IMD layer 54 is preferably made of silicon oxide or ultra low-k (ULK) dielectric layer including but not limited to for example porous material or silicon oxycarbide (SiOC) or carbon doped silicon oxide (SiOCH).

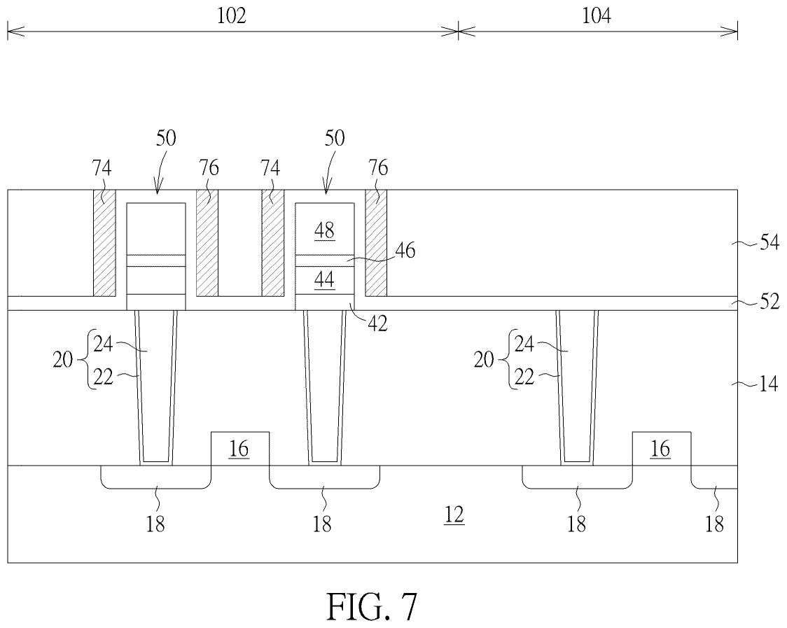

Next, as shown in FIG. 7, a planarizing process such as CMP is conducted to remove part of the IMD layer 54 on the memory region 102 and logic region 104 so that the top surfaces of the IMD layer 54, the spacers 74, 76, and the cap layer 52 are coplanar.

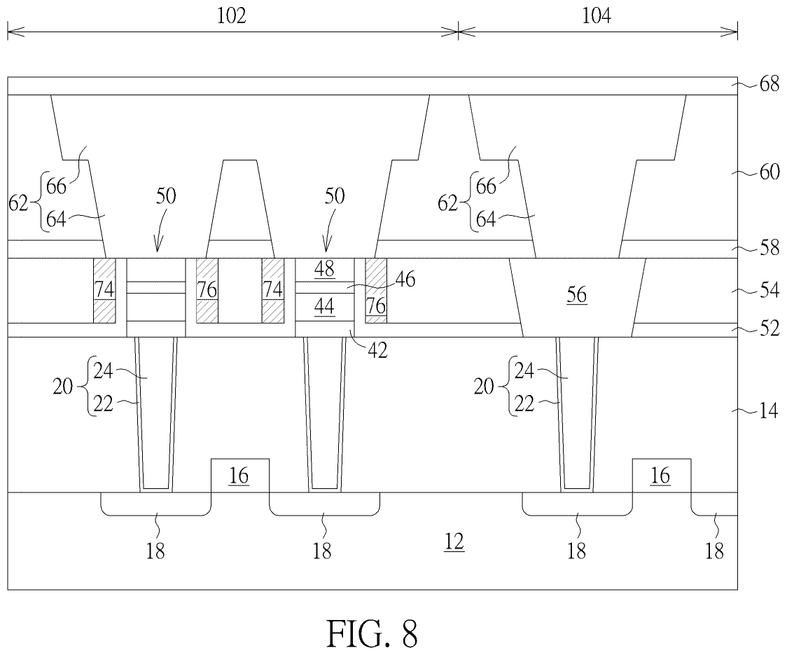

Next, as shown in FIG. 8, another planarizing process such as CMP could be conducted to remove part of the ILD layer 54, part of the spacers 74, 76, part of the cap layer 52, and part of the top electrode 48 so that the top surfaces of the top electrode 48, spacers 74, 76, and cap layer 52 on the memory region 102 and the top surface of the ILD layer 54 on the logic region 104 are coplanar. Next, a patterned transfer process could be conducted by using a patterned mask (not shown) as mask to remove part of the IMD layer 54 and part of the cap layer 52 on the logic region 104 for forming a contact hole (not shown) exposing the contact plug 20 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 56 in the contact hole electrically connecting the contact plug 20 underneath. Next, a stop layer 58 is formed on the IMD layer 54 on the memory region 102 and logic region 104. Preferably, the stop layer 58 is made of nitrogen doped carbide (NDC), silicon nitride, silicon carbon nitride (SiCN), silicon oxynitride (SiON), or combination thereof.

In alternative to conducting a CMP process to remove part of the ILD layer 54, part of the spacers 74, 76, part of the cap layer 52, and part of the top electrode 48 before forming the metal interconnection 56, according to another embodiment of the present invention, it would also be desirable to directly form a metal interconnection 56 on the logic region 104 as soon as the process in FIG. 7 is completed, and then conduct a CMP process to remove part of the ILD layer 54, part of the spacers 74, 76, part of the cap layer 52, part of the top electrode 48, and part of the metal interconnection 56 at the same time so that the top surfaces of the top electrode 48, spacers 74, 76, and cap layer 52 on the memory region 102 are even with top surfaces of the ILD layer 54 and metal interconnection 56 on the logic region 104, which is also within the scope of the present invention.

Next, another IMD layer 60 is formed on the surface of the stop layer 58 and one or more photo-etching process is conducted to remove part of the IMD layer 60 and part of the stop layer 58 on the memory region 102 and logic region 104 to form contact holes (not shown) exposing the top electrode 48 and metal interconnection 56. Next, conductive materials are deposited into the contact holes and a planarizing process such as CMP is conducted to form metal interconnections 62 connecting the top electrode 48 and metal interconnection 56 underneath, and another stop layer 68 is formed on the surface of the metal interconnections 62 thereafter. Similar to the aforementioned metal interconnection 56, the metal interconnections 62 could be embedded within the IMD layer 60 according to a single damascene process or dual damascene process. For instance, each of the metal interconnections 62 on the memory region 102 and logic region 104 could further include via conductors 64 connecting the RRAM 50 and metal interconnection 56 underneath and a trench conductor 66 atop the via conductors 64.

Preferably, the bottom surface of the via conductor 64 on the memory region 102 could directly contacting the top electrode 48, the cap layer 52, and part of the spacers 74, 76 at the same time in this embodiment. Nevertheless, according to other embodiment of the present invention, the bottom surface of the via conductor 64 could only contact the top electrode 48 and spacer 52 directly but not contacting the spacers 74, 76 directly, or even only contacting the top electrode 48 directly but not contacting the cap layer 52 and spacers 74, 76 directly, which are all within the scope of the present invention.

In this embodiment, each of the metal interconnections 62 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Moreover, the IMD layer 60 preferably includes an ultra low-k (ULK) dielectric layer including but not limited to for example porous material or silicon oxycarbide (SiOC) and the stop layer 68 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

Overall, the present invention discloses an approach for fabricating RRAM device, which first forms contact plugs 20 in an ILD layer 14 to electrically or directly connecting active devices such as source/drain regions of a MOS transistor disposed on a substrate and then forms a RRAM 50 made of a bottom electrode 42, a resistor switching layer 44, a capping layer 46, and a top electrode 48 on the contact plugs 20. Next, a cap layer 52 and another cap layer 72 is formed on the RRAM 50 and then part of the cap layer 72 is removed to form spacers 74, 76 on sidewalls of the cap layer 52. By forming composite dielectric materials made of cap layer 52 and spacers 74, 76 adjacent to the RRAM 50, it would be desirable to prevent formation of tiger tooth structure adjacent to two sides of the RRAM 50 when upper level metal interconnection 62 is formed to connect to the top electrode 48 thereby resulting in issues such as electrical short circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating resistive random access memory (RRAM) device, comprising:
forming an interlayer dielectric (ILD) layer on a substrate;
forming a contact plug in the ILD layer;
forming a RRAM on the contact plug;
forming a first cap layer and a second cap layer on the RRAM; and
removing part of the second cap layer to form a spacer.

2. The method of claim 1, wherein the RRAM comprises:
a bottom electrode on the contact plug;
a resistor switching layer on the bottom electrode; and
a top electrode (TE) on the resistor switching layer.

3. The method of claim 1, further comprising:
forming the spacer adjacent to the first cap layer;
forming a first inter-metal dielectric (IMD) layer on the spacer and the first cap layer;
planarizing the first IMD layer;
forming a second IMD layer on the first IMD layer; and
forming a metal interconnection in the second IMD layer to connect to the RRAM.

4. The method of claim 3, wherein top surfaces of the spacer and the first cap layer are coplanar.

5. The method of claim 3, wherein top surfaces of the spacer and the first IMD layer are coplanar.

6. The method of claim 3, wherein top surfaces of the first cap layer and the first IMD layer are coplanar.

7. The method of claim 1, wherein the first cap layer comprises a L-shape.

8. The method of claim 1, wherein the spacer comprises an I-shape.

9. A resistive random access memory (RRAM) device, comprising:
an interlayer dielectric (ILD) layer on a substrate;
a contact plug in the ILD layer;
a RRAM on the contact plug;
a cap layer adjacent to the RRAM; and
a spacer adjacent to the cap layer.

10. The RRAM device of claim 9, wherein the RRAM comprises:
a bottom electrode on the contact plug;
a resistor switching layer on the bottom electrode; and
a top electrode (TE) on the resistor switching layer.

11. The RRAM device of claim 9, further comprising:
a first inter-metal dielectric (IMD) layer around the spacer;
a second IMD layer on the first IMD layer; and
a metal interconnection in the second IMD layer and connected to the RRAM.

12. The RRAM device of claim 11, wherein top surfaces of the spacer and the first IMD layer are coplanar.

13. The RRAM device of claim 11, wherein top surfaces of the cap layer and the first IMD layer are coplanar.

14. The RRAM device of claim 9, wherein top surfaces of the spacer and the cap layer are coplanar.

15. The RRAM device of claim 9, wherein the cap layer comprises a L-shape.

16. The RRAM device of claim 9, wherein the spacer comprises an I-shape.

17. The RRAM device of claim 9, wherein the cap layer and the spacer comprise different materials.
